(19) United States
(12) Patent Application Publication
(10) Pub. No.: US 2025/0190662 A1
(43) Pub. Date: Jun. 12, 2025

(54) TRANSLATION OF INTEGRATED CIRCUIT DESIGN DATA INTO A PRODUCTION FORMAT

(71) Applicant: International Business Machines Corporation, Armonk, NY (US)

(72) Inventors: Robert John Allen, Jericho, VT (US); Mitchell R. DeHond, Essex Junction, VT (US); Margaret Annabelle Allen, Jericho, VT (US); Matthew T. Guzowski, Essex Junction, VT (US); Nathaniel Ogilvie, Huntington, VT (US); Ronald Dennis Rose, Essex Junction, VT (US)

(21) Appl. No.: 18/536,302

(22) Filed: Dec. 12, 2023

(51) Int. Cl. G06F 30/323

(52) U.S. Cl. CPC G06F 30/323

(57) ABSTRACT

Embodiments include translation of an integrated circuit design data into a production file. Aspects of the invention include identifying a top cell in the integrated circuit design data and a first cell-file associated with the top cell, assigning the first cell-file to a first translation module of a plurality of translation modules, and receiving, from the first translation module, an identification of child cells referenced by the first cell-file. Aspects also include assigning cell-files of the integrated circuit design data that correspond to each of the child cells to different translation modules of the plurality of translation modules, receiving, by a merger module, a single-cell production file from each of the plurality of translation modules, wherein each single-cell production file corresponds to a cell in the integrated circuit design data, and combining, by the merger module, the single-cell production files to create the production file.

### BACKGROUND

The present invention generally relates to integrated circuit development, and more specifically, to the translation of integrated circuit design data into a production format.

The development of an integrated circuit (i.e., chip) involves several stages from design through fabrication. The chip may be subdivided into hierarchical levels to simplify design and testing tasks at different stages. Generally, a cell or macro may be regarded as a sub-section of the chip. For example, each macro may comprise a number of cells. Once the design is finalized, tests may be completed to ensure that design rules established by a foundry are met prior to fabrication. Design rules may be applied to sections of the chip. For example, a grid may be overlaid on the chip and each section of the grid (i.e., tile) may be checked for complicity with design rules.

Electronic design automation (EDA) software is often used to create the design of a chip. OpenAccess is an EDA database designed to enable interoperability among chip design tools through an open standard data access interface. One step in very-large-scale integration (VLSI) layout design and chip manufacture is the conversion of chip design data from a format suitable for editors and construction tools (e.g. OpenAccess) to a format used by design rule checking, logic-to-schematic verification, and manufacturing mask creation (e.g. Open Artwork System Interchange Standard (OASIS™), referred to herein as a production format.

### SUMMARY

Embodiments of the present invention are directed to the translation of integrated circuit design data into a production format. A non-limiting example computer-implemented method includes identifying a top cell in the integrated circuit design data and a first cell-file associated with the top cell, assigning the first cell-file to a first translation module of a plurality of translation modules, and receiving, from the first translation module, an identification of one or more child cells referenced by the first cell-file. The method also includes assigning cell-files of the integrated circuit design data that correspond to each of the one or more child cells to different translation modules of the plurality of translation modules, receiving, by a merger module, a single-cell production file from each of the plurality of translation modules, wherein each single-cell production file corresponds to a cell in the integrated circuit design data, and combining, by the merger module, the single-cell production files to create the production file.

Other embodiments of the present invention implement features of the above-described method in computer systems and computer program products.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 is a block diagram of an example computer system for use in conjunction with one or more embodiments of the present disclosure;

FIG. 2 is a block diagram of a system to perform the development of an integrated circuit according to one or more embodiments of the invention;

FIG. 3 is a schematic diagram of a process flow for the translation of integrated circuit design data into a production format according to one or more embodiments of the invention;

FIGS. 4A and 4B are flowchart diagrams illustrating the operation of a manager module according to one or more embodiments of the invention;

FIG. 5 is a flowchart diagram illustrating the operation of a translation module according to one or more embodiments of the invention;

FIG. 6 is a flowchart diagram illustrating the operation of a merger module according to one or more embodiments of the invention;

FIG. 7 is a flowchart diagram illustrating a method for the translation of integrated circuit design data into a production format according to one or more embodiments of the invention; and

FIG. 8 is a schematic diagram of a process flow of a method of fabricating the integrated circuit according to exemplary embodiments of the invention.

The diagrams depicted herein are illustrative. There can be many variations to the diagrams or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

### DETAILED DESCRIPTION

As previously noted, integrated circuit development may involve several stages from design through fabrication. As also noted, one step in VLSI layout design and chip manufacture is the conversion of design data from a format suitable for editors and construction to a format used by design rule checking, logic-to-schematic verification, and manufacturing mask creation.

Currently, the conversion of design data into a production format file is a serial process performed at the chip level, which can take many hours to perform. Parallel processing is often a method of improving overall turnaround time, but there are limitations to the parallelization of reading an integrated circuit (IC) design data. Disclosed herein are methods, systems, and computer program products that utilize parallel processing to translate integrated circuit (IC) design data, such as an OpenAccess data, into a production file, such as an OASIS file. Due to the parallel processing techniques used, the translation of an IC design data into a production file can be performed in a fraction of the time provided by existing tools. Embodiments include the parallelization of the reading of the cells represented in IC design data and subsequently writing single-cell production files for each cell, using a distributed work queue. These single-cell production files are then combined to create a single production file that corresponds to the IC design data. By parallelizing the reading of the IC design data cells and the creation of single-cell production files for each cell, the time required to create a single production file that corresponds to the IC design data can be dramatically reduced.

Various aspects of the present disclosure are described by narrative text, flowcharts, block diagrams of computer systems, and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as translation of integrated circuit design data 150. In addition to block 150, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 150, as identified above), peripheral device set 114 (including user interface (UI), device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

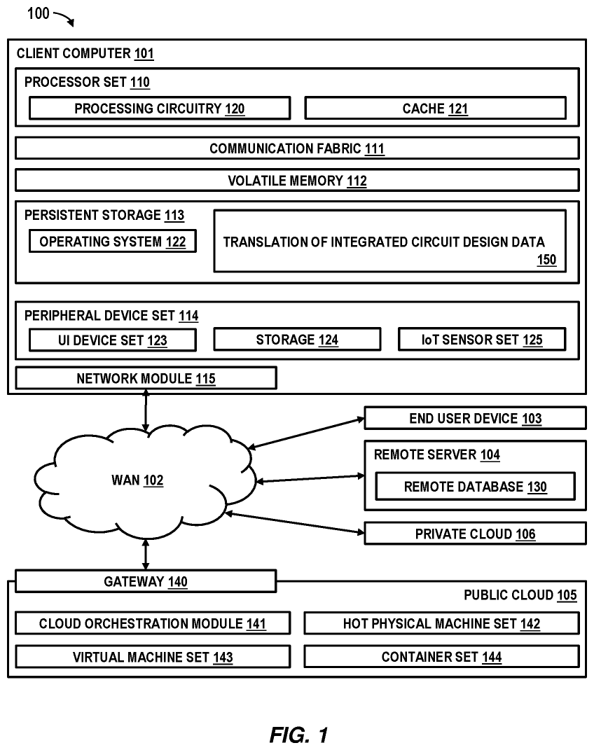

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 150 in persistent storage 113.

COMMUNICATION FABRIC 111 is the signal conduction paths that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface type operating systems that employ a kernel. The code included in block 150 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collects and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

One or more embodiments described herein can utilize machine learning techniques to perform prediction and or classification tasks, for example. In one or more embodiments, machine learning functionality can be implemented using an artificial neural network (ANN) having the capability to be trained to perform a function. In machine learning and cognitive science, ANNs are a family of statistical learning models inspired by the biological neural networks of animals, and in particular the brain. ANNs can be used to estimate or approximate systems and functions that depend on a large number of inputs. Convolutional neural networks (CNN) are a class of deep, feed-forward ANNs that are particularly useful at tasks such as, but not limited to analyzing visual imagery and natural language processing (NLP). Recurrent neural networks (RNN) are another class of deep, feed-forward ANNs and are particularly useful at tasks such as, but not limited to, unsegmented connected handwriting recognition and speech recognition. Other types of neural networks are also known and can be used in accordance with one or more embodiments described herein.

ANNs can be embodied as so-called “neuromorphic” systems of interconnected processor elements that act as simulated “neurons” and exchange “messages” between each other in the form of electronic signals. Similar to the so-called “plasticity” of synaptic neurotransmitter connections that carry messages between biological neurons, the connections in ANNs that carry electronic messages between simulated neurons are provided with numeric weights that correspond to the strength or weakness of a given connection. The weights can be adjusted and tuned based on experience, making ANNs adaptive to inputs and capable of learning. For example, an ANN for handwriting recognition is defined by a set of input neurons that can be activated by the pixels of an input image. After being weighted and transformed by a function determined by the network's designer, the activation of these input neurons are then passed to other downstream neurons, which are often referred to as “hidden” neurons. This process is repeated until an output neuron is activated. The activated output neuron determines which character was input. It should be appreciated that these same techniques can be applied in the case of containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

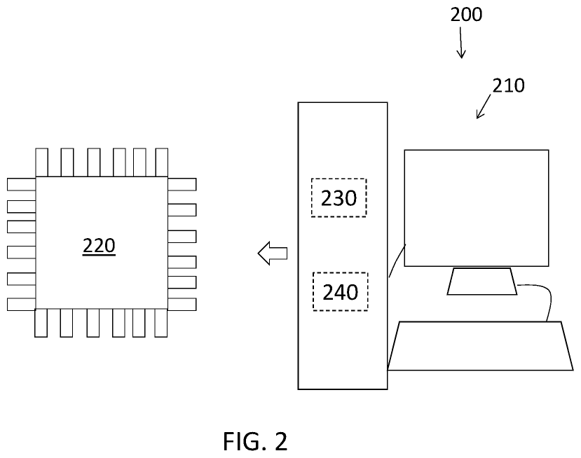

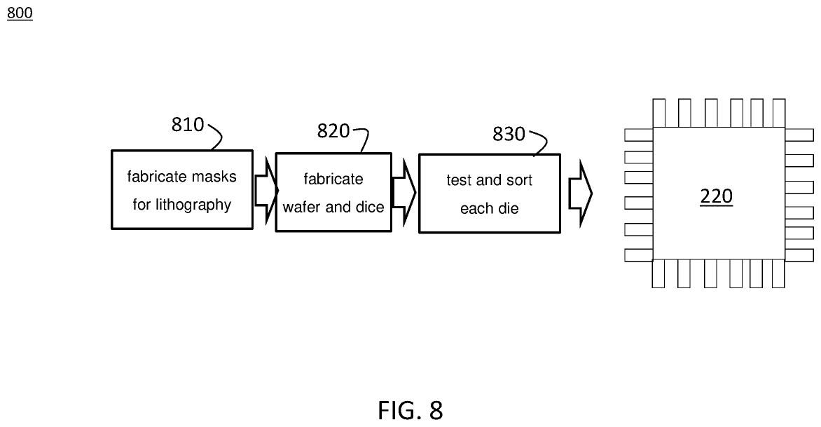

Referring now to FIG. 2, a block diagram of a system 200 to perform the development of an integrated circuit according to embodiments of the invention is shown. The system 200 includes a computer system 210, such as the one shown in FIG. 1, having processing circuitry 230 and memory 240 that is used to generate the design that is ultimately fabricated into an integrated circuit 220. The steps involved in the fabrication of the integrated circuit 220 are well-known and briefly described herein. Once the physical layout is finalized, the finalized physical layout is provided to a foundry. Masks are generated for each layer of the integrated circuit based on the finalized physical layout. Then, the wafer is processed in the sequence of the mask order. The processing includes photolithography and etch. This is further discussed with reference to FIG. 8.

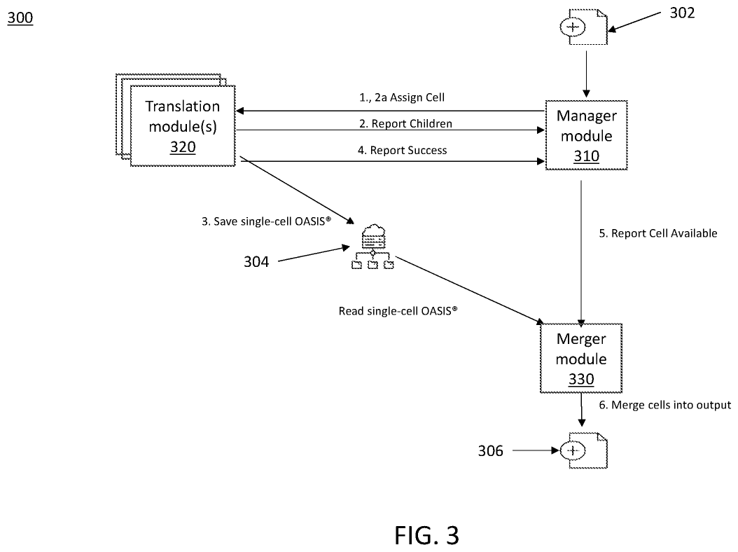

Referring now to FIG. 3, a schematic diagram of a process flow 300 for translation of integrated circuit design data 302, such as an OpenAccess file, to a production file 306 one or more embodiments of the invention is shown. In exemplary embodiments, the process flow 300 is performed by a computer system 210, such as the one shown in FIG. 2, which includes a manager module 310, a plurality of translation modules 320, and a merger module 330. In exemplary embodiments, the manager module 310 obtains the integrated circuit design data 302, such as an OpenAccess file, and identifies a top cell of the integrated circuit (IC). Once the manager module 310 identifies the top cell of the integrated circuit, a file associated with the top cell is assigned to translation module 320. In exemplary embodiments, once assigned a file a translation module 320 is configured to open the file and to identify child cells of the IC referenced within the assigned file. The translation module 320 is configured to transmit information regarding the identified child cells, such as the name of the child cells, back to the manager module 310.

In exemplary embodiments, the translation module 320 is configured to create a single-cell production file 304, for example, a single-cell OASIS file, that corresponds to the assigned file/cell. In one embodiment, creating the single-cell production file includes generating a cell index for the cell based on the name of the assigned file. In one example, a cyclic redundancy check (CRC) hashing scheme is used to generate cell indices that have a low probability of colliding between different cell names and are guaranteed to match for the same name (i.e., parent reference and child definition). The translation module 320 is further configured to save the single-cell production file 304 and to report the completion of the single-cell production file 304 to the manager module 310. In turn, the manager module 310, informs the merger module 330 that the single-cell production file 304 has been completed.

In exemplary embodiments, a plurality of translation modules 320 are configured to process assigned files corresponding to IC cells of the integrated circuit design data 302 in parallel. In exemplary embodiments, the plurality of translation modules 320 are configured to identify and report cells that are referenced by an assigned file/cell back to the manager module 310 before writing the details of the assigned file/cell to the single-cell production file 304. Once the manager module 310 receives an indication of a cell from a translation module 320, the manager module 310 assigns a file associated with the cell to an available translation module 320.

In exemplary embodiments, the merger module 330 is configured to receive an indication of an available single-cell production file 304 from the manager module 310 and to responsively obtain the single-cell production file 304. The merger module 330 is further configured to combine the information from the single-cell production files 304 to create the production file 306. In exemplary embodiments, the creation of the production file 306 by the merger modules 330 includes the creation of an index table that identifies the cell name, cell index, and location of the corresponding cell data in the production file 306. In exemplary embodiments, the merger module 330 is configured to perform conflict checking among the single-cell production files 304 to ensure that unique cell index values for different cells, (i.e., cells that have different names in the integrated circuit design data 302.

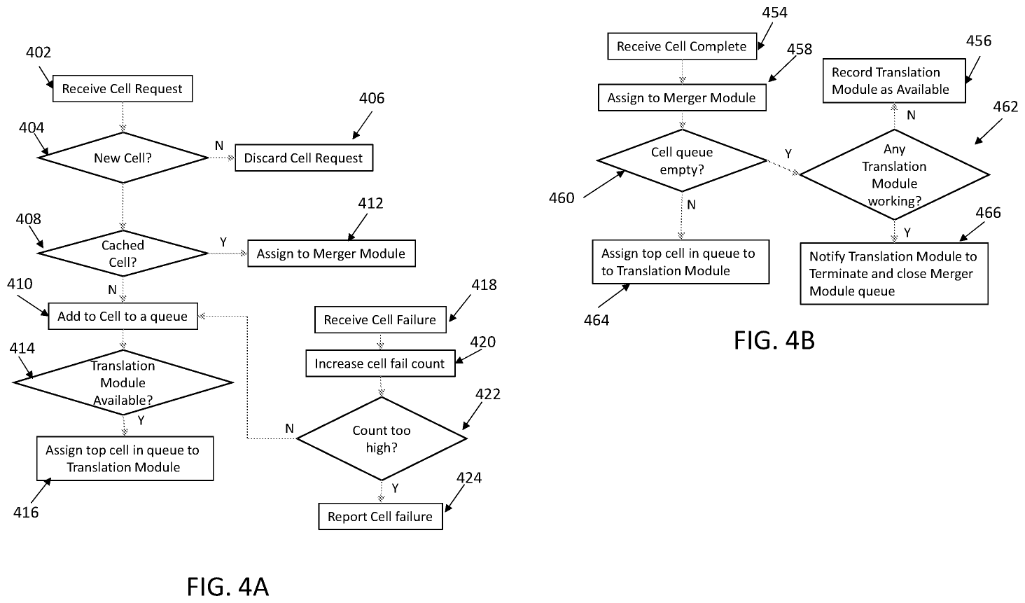

Referring now to FIGS. 4A and 4B, flowchart diagrams illustrating the operation of a manager module according to one or more embodiments of the invention are shown. As shown at block 402, the manager module receives a request to process a cell of the integrated circuit design data. In one embodiment, the request is received from a translation module based on identifying a cell referenced in a file being processed by the translation module. At decision block 404, the manager module determines whether the cell identified in the request is new, (i.e., has this cell already been assigned to a translation module). If the cell has already been assigned to a translation module, the manager module discards the cell request, as shown at block 406. Otherwise, at decision block 408, the manager module determines whether a cell corresponds to a cell that already has a single-cell production file 304 stored in a cache. For example, in some embodiments, the manager module may have access to previously created single-cell production files 304 for one or more cells that were created during another translation process. At block 412, the manager module assigned the cached version of the created single-cell production file 304 to the merger module. At block 410, the manager module adds the cell to a queue to be dispatched to a translation module. At decision block 414, the manage module determines whether a translation module is available. Once a translation module is available, the top cell in the queue is assigned to the translation module, as shown at block 416.

At block 418, the manager module receives an indication that a translation module has failed to successfully create a single-cell production file for the assigned cell. In one embodiment, the indication can be an error message received from the translation module. In another embodiment, the indication may be the expiration of a timer associated with the translation module. Next, at block 420, the manager module increases a failure counter associated with the cell. At decision block 422, the manager module determines whether the failure counter is above a threshold value. Based on a determination that the failure counter is not above the threshold value, the manager module ads the cell back to the queue, at block 410. Otherwise, the manager module reports the failure to a user, as shown at block 424.

At block 454, the manager module receives an indication from a translation module that the translation module on an assigned file/cell has been completed. In exemplary embodiments, the indication includes an identification of a single-cell production file created by the translation module. Next, at block 458, the manager module notifies the merger module that the single-cell production file created by the translation module is ready for the merger module. At decision block 460, the manager module determines whether the cell queue is empty. If the cell queue is not empty, the manager module assigns the top cell in the queue to an available translation module. If the cell queue is empty, the manager module determines whether any translation modules are currently working. If no translation modules are currently working, the manager module notifies the translation module to terminate and closes the merger module queue. Otherwise, at block 456 the manager module records a translation module as being available.

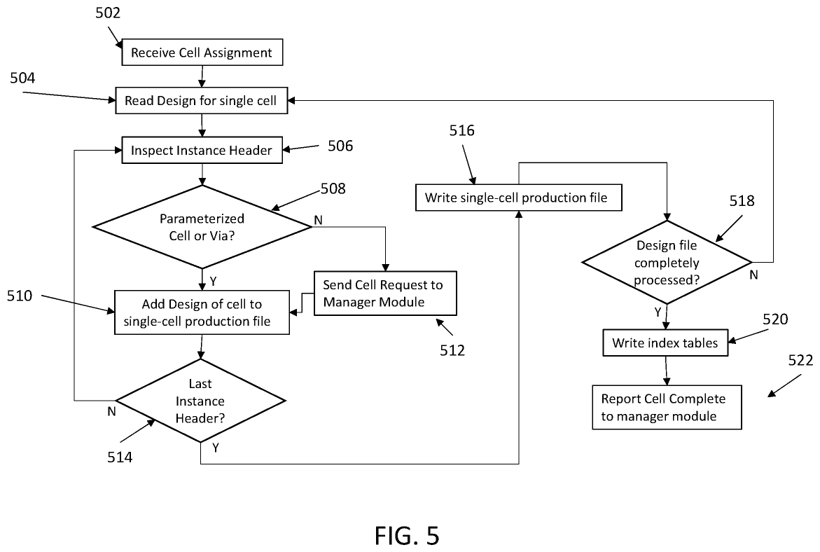

Referring now to FIG. 5, a flowchart diagram illustrating the operation of a translation module according to one or more embodiments of the invention is shown. At block 502, the translation module receives a cell assignment from the manager module. Next, at block 504, the translation module reads the design file for the assigned cell. At block 506, the translation module inspects an instance header in the design file. Next, at decision block 508, the translation module determines whether the instance header references another cell or via. If the instance header references another cell or via, the translation module transmits the information regarding the cell or via to the manager module, as shown at block 512. Next, at block 510, the translation manager adds the information regarding the cell or via to a single-cell production file. Once the information regarding the cell or via to a single-cell production file, the translation manager determines whether the instance header was the last instance header in the design file, as shown at decision block 514. If the instance header was not the last instance header in the design file, the translation manager inspects the next instance header at block 506. Otherwise, the translation manager writes the single-cell production file at block 516. Next, at decision block 518, the translation manager determines whether the entire design file has been completely processed. If the design file has not been completely processed, the translation manager continues the processing of the design file at block 504. Otherwise, the translation manager writes an index table for the single-cell production file, at block 520, and reports completion of the translation of the design file and writing of the single-cell production file to the manager module.

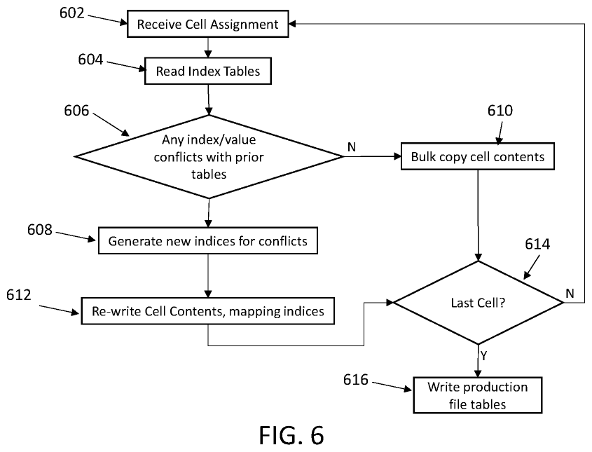

Referring now to FIG. 6, a flowchart diagram illustrating the operation of a merger module according to one or more embodiments of the invention is shown. At block 602, the merger module receives an indication from the manager module that a single-cell production file for a cell is completed. Next, at block 604, the merger module reads the index table from the single-cell production file and the index table from previously received single-cell production files. At decision block 606, the merger module determines if there are any conflicts between the data in the index tables (i.e., do any entries in the indices have the same index values and different cell names). If the merger module determines that there are no conflicts between the data in the index tables, the merger module copies the contents of the single-cell production file to a production file, as shown at block 610. If the merger module determines that there are conflicts between the data in the index tables, the merger module generates a new index value for the cell having the identified conflict, at block 608. Next, at block 612, the merger module re-writes the cell contents with the new index value to single-cell production file and updates the index of the single-cell production file. At decision block 614, the merger module determines whether the received cell assignment was the last cell of the design file. If so, the merger module writes the production file including the index table, at block 616. If the merger module determines that the received cell assignment was not the last cell of the design file, the merger module waits to receive the next cell assignment.

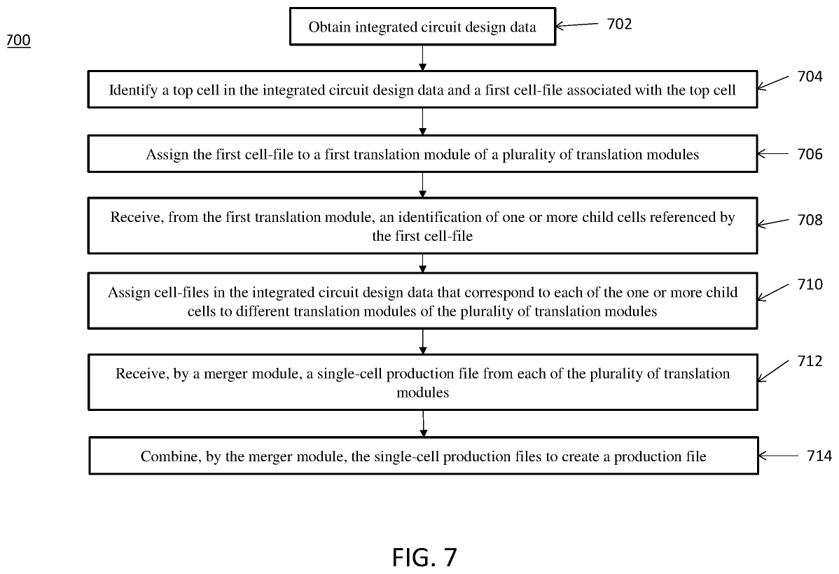

Referring now to FIG. 7, a flowchart diagram illustrating a method 700 for the translation of integrated circuit design data according to one or more embodiments of the invention is shown. At block 702, the method 700 includes obtaining integrated circuit design data. In exemplary embodiments, the integrated circuit design data is an OpenAccess file. In exemplary embodiments, each cell-file of the integrated circuit design data includes a unique name. Next, as shown at block 704, the method 700 includes identifying a top cell in the integrated circuit design data and a first cell-file associated with the top cell.

As shown at block 706, the method 700 includes assigning the first cell-file to a first translation module of a plurality of translation modules. In exemplary embodiments, each of the plurality of translation modules are configured to create a single-cell file that includes an index value based on the unique name. In one embodiment, the index value is created by performing a cyclic redundancy check on the unique name. The translation modules are also configured to analyze the cell-files to identify one or more cells, such as child cells, referenced by the assigned cell-file.

As shown at block 708, the method 700 includes receiving, from the first translation module, an identification of one or more child cells referenced by the first cell-file. Next, at block 710, the method 700 includes assigning cell-files in the integrated circuit design data that correspond to each of the one or more child cells to different translation modules of the plurality of translation modules. In exemplary embodiments, the manager module receives the identification of one or more child cells referenced by the first cell-file. Each of these one or more child cells are assigned by the manager module to a translation module of the plurality of translation modules. This process recursively repeats until all of the child cells referenced throughout the integrated circuit design file have been assigned to translation modules. In exemplary embodiments, one or more of the plurality of translation modules are configured to be executed in parallel.

As shown at block 712, the method 700 includes receiving, by a merger module, a single-cell production file from each of the plurality of translation modules, where each single-cell production file corresponds to a cell in the integrated circuit design data. Next, at block 714, the method 700 includes combining, by the merger module, the single-cell production files to create a production file. In exemplary embodiments, combining the single-cell production files includes performing a conflict check between the index values of each of the single-cell production files. In one embodiment, combining the single-cell production files further includes appending an index table that includes an index value, a file name, and a location offset for each single-cell production file data within the production file. In one embodiment, the production file is an OASIS file.

FIG. 8 is a process flow of a method 800 of fabricating the integrated circuit according to exemplary embodiments of the invention. Once the physical design data is obtained, based, in part, on the processes discussed with reference to FIG. 3, the integrated circuit 220 can be fabricated according to known processes that are generally described with reference to FIG. 8. Generally, a wafer with multiple copies of the final design is fabricated and cut (i.e., diced) such that each die is one copy of the integrated circuit 220. At block 810, the processes include fabricating masks for lithography based on the finalized physical layout. At block 820, fabricating the wafer includes using the masks to perform photolithography and etching. Once the wafer is diced, testing and sorting each die is performed, at block 830, to filter out any faulty die.

Various embodiments of the invention are described herein with reference to the related drawings. Alternative embodiments of the invention can be devised without departing from the scope of this invention. Various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. Moreover, the various tasks and process steps described herein can be incorporated into a more comprehensive procedure or process having additional steps or functionality not described in detail herein.

One or more of the methods described herein can be implemented with any or a combination of the following technologies, which are each well known in the art: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description, but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of +8% or 5%, or 2% of a given value.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instruction by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method for translation of an integrated circuit design data into a production file, the method comprising:
identifying a top cell in the integrated circuit design data and a first cell-file associated with the top cell;
assigning the first cell-file to a first translation module of a plurality of translation modules;
receiving, from the first translation module, an identification of one or more child cells referenced by the first cell-file;
assigning cell-files of the integrated circuit design data that correspond to each of the one or more child cells to different translation modules of the plurality of translation modules;
receiving, by a merger module, a single-cell production file from each of the plurality of translation modules, wherein each single-cell production file corresponds to a cell in the integrated circuit design data; and
combining, by the merger module, the single-cell production files to create the production file.

2. The method of claim 1, wherein each cell-file of the integrated circuit design data include a unique name.

3. The method of claim 2, wherein each of the plurality of translation modules is configured to create a single-cell file that includes an index value based on the unique name.

4. The method of claim 3, wherein the index value is created by performing cyclic redundancy check on the unique name.

5. The method of claim 3, wherein combining the single-cell production files includes performing a conflict check between index values of each of the single-cell production files.

6. The method of claim 1, wherein one or more of the plurality of translation modules are configured to be executed in parallel.

7. The method of claim 1, wherein the combining further includes appending an index table that includes an index value, a file name, and a location offset for each single-cell production file data within the production file.

8. The method of claim 1, wherein the integrated circuit design data is an OpenAccess file.

9. The method of claim 1, wherein the production file is an OASIS file.

10. A system comprising:
a memory having computer readable instructions; and
one or more processors for executing the computer readable instructions, the computer readable instructions controlling the one or more processors to perform operations comprising:
identifying a top cell in the integrated circuit design data and a first cell-file associated with the top cell;
assigning the first cell-file to a first translation module of a plurality of translation modules;
receiving, from the first translation module, an identification of one or more child cells referenced by the first cell-file;
assigning cell-files of the integrated circuit design data that correspond to each of the one or more child cells to different translation modules of the plurality of translation modules;
receiving, by a merger module, a single-cell production file from each of the plurality of translation modules, wherein each single-cell production file corresponds to a cell in the integrated circuit design data; and
combining, by the merger module, the single-cell production files to create the production file.

11. The system of claim 10, wherein each cell-file of the integrated circuit design data include a unique name.

12. The system of claim 11, wherein each of the plurality of translation modules is configured to create a single-cell file that includes an index value based on the unique name.

13. The system of claim 12, wherein the index value is created by performing cyclic redundancy check on the unique name.

14. The system of claim 12, wherein combining the single-cell production files includes performing a conflict check between index values of each of the single-cell production files.

15. The system of claim 10, wherein one or more of the plurality of translation modules are configured to be executed in parallel.

16. The system of claim 10, wherein the combining further includes appending an index table that includes an index value, a file name, and a location offset for each single-cell production file data within the production file.

17. The system of claim 10, wherein the integrated circuit design data is an OpenAccess file.

18. The system of claim 10, wherein the production file is an OASIS file.

19. A computer program product comprising a computer readable storage medium having program instructions embodied therewith, the program instructions executable by a processor to cause the processor to perform operations comprising:
identifying a top cell in the integrated circuit design data and a first cell-file associated with the top cell;
assigning the first cell-file to a first translation module of a plurality of translation modules;
receiving, from the first translation module, an identification of one or more child cells referenced by the first cell-file;
assigning cell-files of the integrated circuit design data that correspond to each of the one or more child cells to different translation modules of the plurality of translation modules;
receiving, by a merger module, a single-cell production file from each of the plurality of translation modules, wherein each single-cell production file corresponds to a cell in the integrated circuit design data; and
combining, by the merger module, the single-cell production files to create the production file.

20. The computer program product of claim 19, wherein the combining further includes appending an index table that includes an index value, a file name, and a location offset for each single-cell production file data within the production file.
